(19) United States
(12) Patent Application Publication
(10) Pub. No.: US 2024/0321649 A1
(43) Pub. Date: Sep. 26, 2024

(54) ON-THE-FLY MEASUREMENT OF SUBSTRATE STRUCTURES

(71) Applicant: Applied Materials, Inc., Santa Clara, CA (US)

(72) Inventors: Amikam Sade, Sunnyvale, CA (US); Michael Kutney, Santa Clara, CA (US)

(21) Appl. No.: 18/611,531

(22) Filed: Mar. 20, 2024

Related U.S. Application Data
(60) Provisional application No. 63/492,199, filed on Mar. 24, 2023.

(51) Int. Cl. H01L 21/66; G01N 21/41; G01N 21/95

(52) U.S. Cl. CPC H01L 22/12; G01N 21/41; G01N 21/9501

(57) ABSTRACT

A method includes determining a plurality of measurement targets of a substrate. The substrate includes a plurality of structures. Each measurement target is associated with a structure of the plurality of structures. The method further includes operating one or more motors to cause motion of a substrate support to dispose a first measurement target within a field of view of a measurement instrument. The method further includes causing the measurement instrument to take a first measurement of the first measurement target as the first measurement target passes through the field of view of the measurement instrument. The method further includes operating the one or more motors of the substrate support to dispose a second measurement target of the substrate within the field of view of the measurement instrument.

### RELATED APPLICATION

This application claims the benefit of U.S. Provisional Patent Application No. 63/492,199, filed Mar. 24, 2023, entitled “ON-THE-FLY MEASUREMENT OF SUBSTRATE STRUCTURES,” which is incorporated by reference herein.

### TECHNICAL FIELD

The present disclosure relates to methods of performing measurement of substrates. More particularly, the present disclosure relates to methods for performing on-the-fly measurements of substrate structures.

### BACKGROUND

Products, such as semiconductor wafers, may be producing by performing one or more manufacturing processes using manufacturing equipment. For example, semiconductor manufacturing equipment may be used to produce substrates via semiconductor manufacturing processes. Determining properties of the substrates may be helpful for determining performance of the manufacturing equipment, performance of the manufacturing process, suitability of the substrates to a target application, or the like.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular embodiments of the disclosure or any scope of the claims. Its sole purpose is to present some concepts of the disclosure in a simplified form as a prelude to the more detailed description that is presented later.

In one aspect of the present disclosure, a method includes determining a plurality of measurement targets of a substrate. The substrate includes a plurality of structures. Each measurement target is associated with a structure of the plurality of structures. The method further includes operating one or more motors to cause motion of a substrate support to dispose a first measurement target within a field of view of a measurement instrument. The method further includes causing the measurement instrument to take a first measurement of the first measurement target as the first measurement target passes through the field of view of the measurement instrument. The method further includes operating the one or more motors of the substrate support to dispose a second measurement target of the substrate within the field of view of the measurement instrument.

In another aspect of the present disclosure, a non-transitory machine-readable storage medium stores instructions which, when executed, cause a processing device to perform operations. The operations include determining a plurality of measurement targets of a substrate. The substrate includes a plurality of structures. Each measurement target is associated with a structure of the plurality of structures. The operations further include operating one or more motors to cause motion of a substrate support to dispose a first measurement target within a field of view of a measurement instrument. The operations further include causing the measurement instrument to take a first measurement of the first measurement target as the first measurement target passes through the field of view of the measurement instrument. The operations further include operating the one or more motors of the substrate support to dispose a second measurement target of the substrate within the field of view of the measurement instrument.

In another aspect of the present disclosure, a system includes memory and a processing device coupled to the memory. The processing device is configured to determine a plurality of measurement targets of a substrate. The substrate includes a plurality of structures. Each measurement target is associated with a structure of the plurality of structures. The processing device is further configured to operate one or more motors to cause motion of a substrate support to dispose a first measurement target within a field of view of a measurement instrument. The processing device is further configured to cause the measurement instrument to take a first measurement of the first measurement target as the first measurement target passes through the field of view of the measurement instrument. The processing device is further configured to operate the one or more motors of the substrate support to dispose a second measurement target of the substrate within the field of view of the measurement instrument.

### BRIEF DESCRIPTION OF THE DRAWINGS

The present disclosure is illustrated by way of example, and not by way of limitation. It should be noted that different references to “an” or “one” embodiment in this disclosure are not necessarily to the same embodiment, and such references mean at least one.

FIG. 1 is a top-down diagram of a substrate support including zones, according to some embodiments.

FIG. 2 depicts a layout of substrate, according to some embodiments.

FIG. 3 depicts a measurement system for performing measurements of a substrate with included structures, according to some embodiments.

FIG. 4 depicts example measurement path for performing measurements of a substrate, according to some embodiments.

FIG. 5 is a flow diagram of a method associated with performing on-the-fly measurement of a substrate including structures, according to some embodiments.

FIG. 6 is a block diagram illustrating a computer system, according to some embodiments.

### DETAILED DESCRIPTION

Described herein are technologies related to determining one or more properties of a substrate by on-the-fly measurement. Manufacturing equipment (e.g., processing chambers) is used to produce substrates, such as semiconductor wafers. The properties of substrates are determined by the conditions in which the substrates were processed. Components of the processing chamber impact conditions proximate to the substrate, and have an effect on performance (e.g., target substrate properties, consistency of production, etc.). As technical requirements for substrate manufacturing become more stringent, additional monitoring of substrate properties may be performed. Additional monitoring of substrate properties (e.g., through metrology) may increase an amount of manufacturing time used to generate a product, reduce throughput through a tool or facility, necessitate additional equipment to meet target production thresholds, etc.

In some systems, a substrate including structures may have one or more properties of the substrate structures measured. Properties of interest may include structure thickness, critical dimension (CD), optical properties (e.g., refractive index, extinction coefficient), chemical properties, electrical properties, etc. In some systems, substrate structures may be measured using a measurement system that detects electromagnetic radiation. Substrate structures may be measured using a measurement system the detects reflected radiation. Substrate structures may be measured by a variety of techniques including reflectometry, ellipsometry, eddy-current tests, non-optical technologies, etc. Substrate structures may be measured using a measurement system that detected infrared radiation. In some systems, substrate structures may be small, e.g., the size of a substrate structure may be on the same order of magnitude as a field of view of a measurement instrument.

In some systems, a substrate may be supported by a substrate support. The substrate support may be coupled to one or more motors for moving the substrate support. In some systems, the substrate support may be coupled to a motor configured to generate linear motion of the substrate support and a motor configured to generate rotational motion of the substrate support. By utilizing two motors spanning different dimensions, any portion of a substrate may be brought into a field of view of a measurement instrument.

In some systems, a measurement target, substrate structure, portion of a substrate, or the like may be brought into the field of view of a measurement instrument. Performing the alignment of a measurement target and a field of view of a measurement instrument may include correlating substrate coordinates to substrate support coordinates, locating an offset between a location of a substrate and an expected substrate location, or the like. Moving a substrate structure to the field of view of the measurement instrument may include accelerating one or more motors of the substrate support, maintaining a speed of the one or more motors, decelerating the one or more motors, allowing for motion settle, etc. The substrate support may stop while a measurement target is within the field of view of the measurement instrument. A target number of measurements may be taken. Motors may then accelerate the substrate support. The substrate support may be moved such that another measurement target is in the field of view of the measurement instrument. In some embodiments, many measurement sites may be visited on a single substrate. Measurement sites in the dozens, hundreds, or thousands may be measured. The substrate support may be moved such that the substrate is relocated, e.g., to another chamber. A considerable amount of time can be consumed by motor start, accelerate, decelerate, and settle operations. Throughput of substrates through measurement operations, especially measurement operations including multiple measurement targets, may be lowered by many motor accelerate, decelerate, and settle operations.

Methods and systems of the present disclosure may address one or more shortcomings of conventional systems. In some embodiments, a substrate for measurement may be provided. The substrate may include a number of structures. A measurement instrument may be utilized in measuring the structures. A field of view of the measurement instrument may be similar in size to structures of the substrate. A randomly selected measurement location on the surface of the substrate (e.g., a randomly located spot the size of the field of view) may be likely to land between structures of the substrate, between structures of interest, may overlap with multiple adjacent structures, etc.

In some embodiments, a set of structures may be selected for measurement. The set of structures may be localized to a spatial region of the substrate. The set of structures may sample many regions of the substrate. A path for motors of the substrate support to maneuver the stage through, such that each of the set of structures passes through the measurement instrument field of view, may be constructed. The motors may cause the substrate to travel along the prescribed path, without stopping for each measurement, e.g., measurements may be taken on-the-fly.

In some embodiments, one or more constraints may be considered when designing a path for the substrate to take. Stage motion constraints may be taken into account. For example, a maximum and minimum velocity of the stage, a maximum acceleration and jerk of the stage, a transformation between stage coordinates and substrate coordinates, etc. Measurement instrument constraints may be considered. A maximum and minimum rate of measurement, a target measurement time, a size and spatial extent of the field of view, etc., may be considered in determining a path. Constraints of the application may be considered, such as target signal to noise characteristics, target substrate throughput, target regions of interest of the substrate, etc.

A measurement instrument may include one or more components that facilitate generation of data for a substrate. For example, a measurement instrument may include a spectrum sensing component for generating spectral data. One or more components may be interchangeable or adaptable, e.g., to facilitate different types of measurements, to facilitate measuring different substrate properties of interest, or the like. The measurement instrument may generate reflectometry data, ellipsometry data, imaging data, hyperspectral imaging data, chemical imaging data (e.g., x-ray photoelectron spectroscopy, energy-dispersive x-ray spectroscopy, x-ray fluorescence, etc.). The measurement instrument may be or include a pulsed reflectometry instrument. The measurement instrument (or other components of the measurement system) may further include positional components to select, identify, and/or modify position and/or orientation of the substrate, e.g., with respect to one or more components of the measurement instrument. A measurement instrument may record reflected intensity of one or more wavelengths or polarized light reflected from a portion of a substrate. The measurement instrument may collect thermal data, spectral data, intensity data, etc. The measurement instrument may include one or more eddy sensors, capacitive sensors, etc.

In some embodiments, a measurement instrument may be an optical measurement device. In some embodiments, the measurement instrument may include an electromagnetic radiation detector. In some embodiments, the measurement instrument may be or include a reflectometer. In some embodiments, the measurement instrument may be or include an infrared reflectometer. The measurement instrument may perform ellipsometry, eddy-current tests, other non-optical measurement techniques, etc. The measurement instrument may be a pulsed instrument, e.g., may take measurements periodically according to a measurement frequency. In some embodiments, a path to be taken by a substrate may be selected such that movement of a target measurement site into the field of view of the measurement instrument correlates temporally with a pulse of the measurement instrument. In some embodiments, a frequency or period of measurement may be adjusted to account for travel time of a substrate between two measurement sites. In some embodiments, one or more measurement pulses may be disregarded that do not correspond to a measurement site being in the measurement instrument field of view.

In some embodiments, a statistical metric may be utilized in determining properties of the substrate. For example, as measurements of the substrate are taken, they may be grouped together according to corresponding spatial regions of the substrate. The spatial regions may correspond to groups of structures of the substrate, such as dies, fields, or the like. The spatial regions may correspond to other grouping of interest, such as measurement targets associated with a particular region (such as a heater zone) of a substrate support, a particular region of processing equipment (such as a plasma source of an array of plasma sources), etc. A number of measurement of a particular spatial region may be considered together to provide an estimate of properties of the region. This may be performed by grouping measurements into a set of groups based on spatial proximity, spatial region, pattern region (e.g., die or field), region associated with a particular region or component of a process chamber, or the like. For example, an average of thickness values measured for a die may serve as an average value of thickness for the die. Signal to noise ratio may be improved by increasing the number of measurement sites in a target zone or area of the substrate. In some embodiments, each measurement site may correspond to a memory block, and a region of the substrate may correspond to a group of nearby memory blocks. Each measurement site may correspond to a structure other than a memory block. Each measurement site may correspond to a target region of the substrate.

Methods and systems of the present disclosure provide technical advantages over conventional methods. Performing measurements of a substrate in accordance with the present disclosure may reduce time delays in the measurement process. A typical measurement process includes many operations of starting stopped motors, accelerating a substrate support, decelerating the substrate support, and waiting for motion settle to facilitate taking measurement of a measurement site. By performing measurements of a series of substrate structures on-the-fly, delays associated with starting and stopping motors for each measurement site may be avoided. Time devoted to measurement of a substrate may be decreased. Decreasing a time for measurement of a substrate may improve processing throughput of the substrate. Improving processing throughput may be more efficient in terms of energy expenditure, environmental impact of processing, material expenditure such as process gas, delays in processing due to a measurement queue, etc. Decreasing a time for measurement of a substrate may enable a large portion of manufactured substrates to be monitored. Monitoring a larger portion of manufactured substrates may enable earlier recognition of processing errors, equipment errors, input material errors, required maintenance, etc. Monitoring a larger portion of manufactured substrates may enable more agile repairs, reconditioning, adjustments of process recipes, component replacement, etc. Monitoring a larger portion of manufactured substrates may reduce a number of faulty substrates produced, reducing energy and material cost, reducing cost associated with disposing of faulty substrates, reducing environmental impact from wasted energy and material, etc.

In some aspects of the present disclosure, a method includes determining a plurality of measurement targets of a substrate. The substrate includes a plurality of structures. Each measurement target is associated with a structure of the plurality of structures. The method further includes operating one or more motors to cause motion of a substrate support to dispose a first measurement target within a field of view of a measurement instrument. The method further includes causing the measurement instrument to take a first measurement of the first measurement target as the first measurement target passes through the field of view of the measurement instrument, without stopping motion of the substrate support. The method further includes operating the one or more motors of the substrate support to dispose a second measurement target of the substrate within the field of view of the measurement instrument.

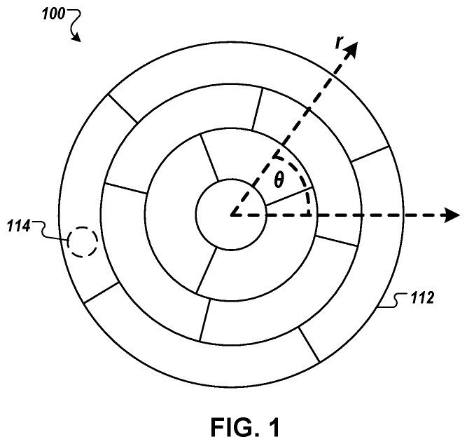

FIG. 1 is a top-down diagram of a substrate support 100 including zones, according to some embodiments. Substrate support 100 may be understood in terms of a coordinate system mapping locations on the substrate support 100. Substrate support 100 may be understood/mapped by an (r, θ) coordinate system, as shown. A substrate supported by substrate support 100 may be mapped by a different set of coordinates, e.g., a different set of (r, θ) coordinates, a set of linear coordinates such as (x, y) coordinates, or the like. A transformation may enable a set of coordinates as related to the substrate support to be mapped to a set of coordinates of a corresponding substrate, such as another substrate associated with the substrate support. A transformation may enable a positioning of the substrate support, as achieved by motors of the substrate support, to be mapped to a location on the substrate, such as a target structure of the substrate. One or more coordinate transformations may enable properties imparted on a substrate by a substrate support (e.g., differences in various zones of a substrate support) to be understood based on measurements of the substrate performed while the substrate is on a different support (e.g., of a metrology system).

Substrate support 100 includes a number of zones 112. The zones may include separate hardware. For example, zones may be associated with different heating elements, chucking elements, back gas outlet zones, combinations of these components, or the like. One or more zones may be targeted for understand the effect of the zones on substrate manufacturing. Measurement of one or more structures of a substrate that are associated with a zone 112 may enable an understanding of properties of the zone. Measurement of one or more structure of a substrate associated with a zone 112 may enable recommendations of corrective actions associated with the zone.

Substrate support 100 includes target measurement area 114. Measurements of a substrate may be performed, which may enable understanding of a performance of a zone of a substrate support (e.g., zone 112), an area of substrate support 100 (e.g., area 114), or the like. In some embodiments, measurements taken from portions of a substrate associated with a target measurement area such as target measurement area 114 may be utilized in determining performance of a zone of substrate support 100. For example, measurements of a substrate that are supported by target measurement area 114, or had been supported by target measurement area 114 during process operations, may be utilized in generating an understanding of performance of substrate support 100, a particular zone of substrate support 100, target measurement area 114, or the like.

In some embodiments, measurements of a substrate associated with substrate support 100 may be made in an on-the-fly manner. For example, measurements of a substrate may be made without stopping motors of a stage of a measurement system. In some embodiments, a measurement system (such as a reflectometry system) may include substrate support 100. In some embodiments, a different substrate support may be utilized for the measurement system, and information associated with target regions of the substrate may be indicative of performance of corresponding regions of substrate support 100, which was in use during processing of the substrate.

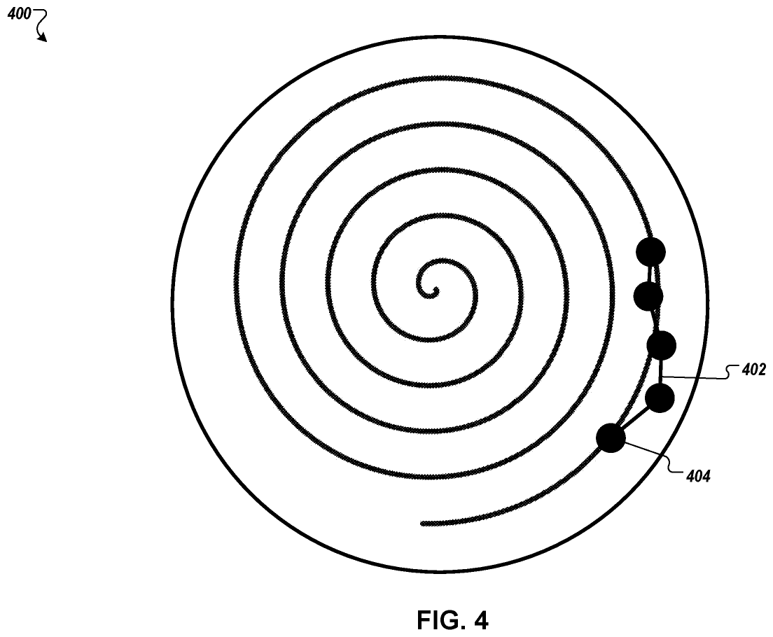

In some embodiments, on-the-fly measurements may be taken based on an arrangement of motors of a stage of a measurement system, such as motors of substrate support 100. For example, substrate support 100 may include two-dimensional control of a substrate position. The two-dimensional control may determine an efficient movement pattern for measurement of the substrate. In some embodiments, a first motor may cause linear movement of a substrate relative to a measurement tool, and a second motor may cause rotational movement of the substrate. A spiral pattern of measurement may be utilized for an on-the-fly measurement of a substrate in such a case. In some embodiments, a target measurement area 114 may include multiple measurements (e.g., of substrate thickness, critical dimension, index of refraction, extinction coefficient, film thickness, or another metric of interest) that may be used to determine behavior associated with target measurement area 114 (e.g., via an average, median, or other statistical metric associated with the measurements). In some embodiments, measurements that are taken separately in time (e.g., across multiple passes of a spiral measurement pattern) may be included in target measurement area 114, may be included in statistical metrics of measurement of the substrate, or the like. Further description of a path of on-the-fly measurements is provided in connection with FIG. 4.

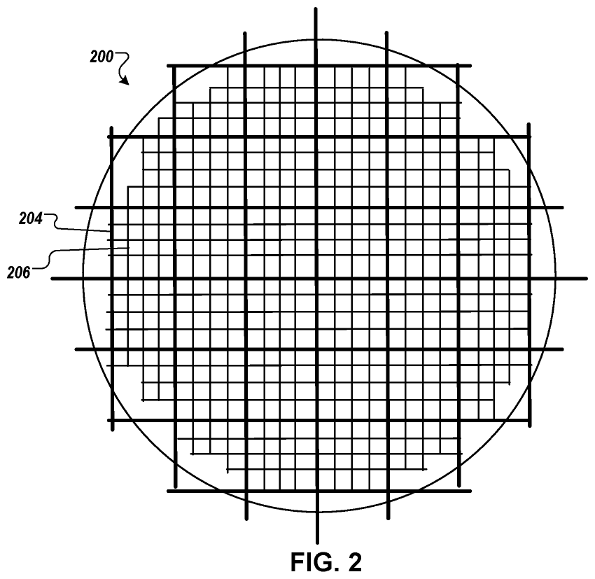

FIG. 2 depicts a layout of substrate 200, according to some embodiments. Substrate 200 may be a semiconductor wafer, Substrate 200 may have a number of structures upon the surface of the substrate. Substrate 200 may have a number of memory blocks on the surface of substrate 200. Substrate 200 may be a substrate that has undergone substrate processing procedures. In some embodiments, substrate 200 may be approximately 30 cm in diameter.

A processed substrate including structures may have the structures organized into regions on the surface of the substrate. For example, substrate 200 is separated into a number of fields, which are further separated into a number of dies, as shown. In some embodiments, measurements of a target die may be grouped together. For example, measurements of structures of a die may be averaged to determine properties of the die. In another example, measurements of structures of a field may be averaged to determine properties of the field.

Substrate 200 includes field 204. Field 204 includes a number of dies, including die 206. Each die may include a number of memory blocks. Measurements of a substrate may target measurements of a memory block, measurements of a die, measurements of a field, or the like. Measurements of a target area (e.g., memory block, die, field, heater region of a substrate support, or another target area) of a substrate may be made in an on-the-fly manner, e.g., without stopping motion of the substrate relative to a metrology device for performing measurements. In some embodiments, multiple measurements of the same target area may be used to overcome shortcomings of resolution, accuracy, reliability, or the like introduced by performing measurements on-the-fly. In some embodiments, multiple measurements may be taken of the same memory block, of the same die, or of the same field, and statistical analysis (e.g., mean, median, outlier removal, quartile analysis, etc.) may be utilized to determine properties of the target area.

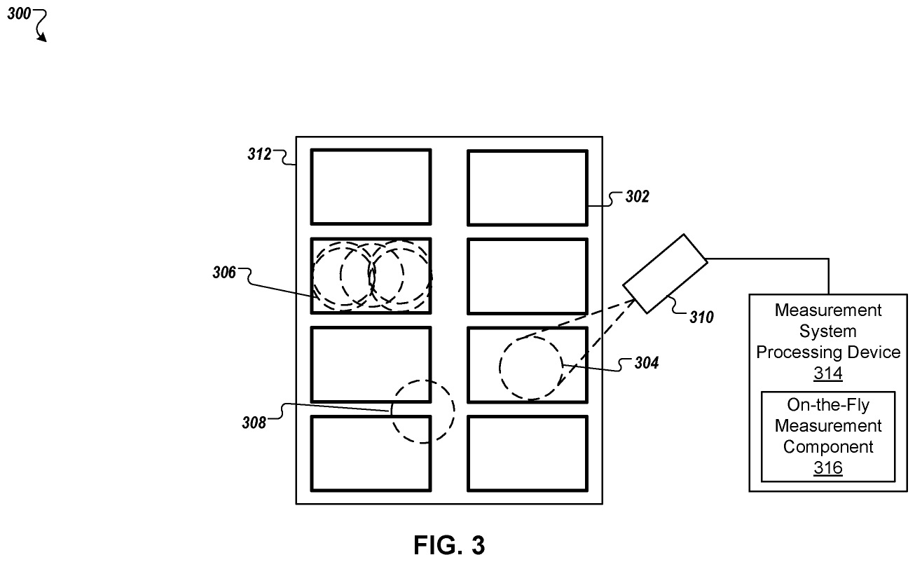

In some embodiments, die 206 may include a number of memory blocks. Example memory block structure is depicted in FIG. 3. A number of measurements may be performed in an on-the-fly procedure of die 206. A number of measurements may be performed on a single memory block of die 206, multiple measurements may be made corresponding to different memory blocks of die 206, or the like.

In some embodiments, one or more dies (e.g., die 206), one or more fields (e.g., field 204), or one or more other regions of a substrate may be targeted for metrology measurements, e.g., via a reflectometry system. An on-the-fly measurement path may be established that includes a target number of measurements of the target measurement area, e.g., to enable sufficient statistical certainty that the outcome of the measurements is meaningful. An on-the-fly measurement path may be established that enables continuous motion of one or more motors associated with positioning substrate 200 relative to a reflectometry device, metrology device, optical measurement device, or other measurement device. An on-the-fly measurement path may be determined that is consistent with one or more constraints of the system, such as maximum speed of one or more motors, maximum acceleration of one or more motors, maximum acceleration that can be tolerated by the substrate (e.g., without slippage), maximum jerk that may be tolerated by the system, frequency of measurement of the system, flexibility of frequency of measurement of the system, target size and locations, target signal to noise ratio, target number of measurements of a region of substrate 200, target throughput, motor resolution, motor jitter, motor timing resolution and jitter, measurement system timing resolution, accuracy, and jitter, etc. On-the-fly measurement paths are discussed further in connection with FIG. 4.

FIG. 3 depicts a measurement system 300 for performing measurements of a substrate with included structures, according to some embodiments. Die 312 may be a die of a substrate, alternatively a system such as measurement system 300 may be performed on a substrate that is not separated into fields, dies, or the like. Die 312 may be a die as depicted as a small box in FIG. 2, e.g., die 206 may correspond to die 312. Die 312 may be a die of a substrate. Die 312 may be a die of a substrate that is to be measured by an on-the-fly measurement system for substrates including structures. Die 312 includes a number of structures such as structure 302. Structures such as structure 302 may be memory blocks. A die (e.g., die 312) may include any number of structures of interest, e.g., any number of memory blocks, such as about ten memory blocks per die.

FIG. 3 depicts example measurement system 300, including measurement field 304. Measurement field 304 may correspond to a spatial extend of a field of view of a measurement instrument, such as a reflectometer. Measurement field 304 may be brought into alignment with a structure 302 to determine one or more properties of the structure 302. FIG. 3 also depicts off-structure measurement field 308. In some embodiments, a measurement may target a structure 302, instead of overlapping structures, the space between structures, or the like.

Measurement field 304 may correspond to resolution of a measurement or metrology instrument. Measurement field 304 may be smaller than a target measurement area of interest, such as a memory block, structure 302, or the like. In some embodiments, measurement field 304 may have a size that includes or accounts for some imprecision of the metrology system, such as jitter in motor motion or the like being conceptualized as a larger size of measurement field 304. In some embodiments, measurement field 304 may be of a similar size as a target measurement region, e.g., as shown in FIG. 3, measurement field 304 is of similar size to structure 302. A measurement field may be significantly smaller than a target measurement area, which may reduce constraints (e.g., introduce less stringent constraints) on relative positions of measurement system and substrate when measurements are performed in an on-the-fly measurement system.

Off-structure measurement field 308 depicts a measurement that may be performed that includes a border of a target structure, a space in between target structures, multiple structures, or the like. In some embodiments, measurements such as off-structure measurement field 308 may not be included in target measurements, for example, target measurements may include a target structure. An on-the-fly measurement technique may determine a measurement path subject to the constraints of the metrology system. The measurement path may avoid off-structure measurements. The measurement path may include off-structure measurements, but further processing of the measurement data may include excluding measurements that are off-structure, that do not measure targets of interest, or the like. A measurement path may be determined that includes several measurements of a target structure, such as structure 302. A measurement path may be determined that includes several measurements of a target structure separated between multiple “passes” of the on-the-fly system, e.g., a rotational motor may cause several rotations of a substrate, with one or more measurements of a target structure performed at each rotation.

In some embodiments, a target structure may be somewhat larger than a field of view of a measurement instrument. Field selections 306 depict a range of fields that span a space of acceptable measurement to capture properties of a structure of die 312. In some embodiments, selection of measurement targets may include selection of particular structures of a substrate to measure. In some embodiments, selection of measurement targets may include selecting which portion of a structure may be overlapping with the field of view of a measurement instrument when the measurement is taken. Selecting a measurement site from a chosen measurement target may be done in accordance with one or more system constraints. Selecting a measurement site may include selecting a site that enables motor control constraints to be within a target window. Selecting a measurement site may include selecting a site that enables motor acceleration to be below a threshold, minimized, or the like. Selecting a measurement site may include selecting a site that enables a target measurement frequency, e.g., minimizes deviation from a frequency of measurement associated with the measurement instrument.

In some embodiments, multiple measurements may be taken of a single structure, target measurement site, or the like. For example, multiple measurements of multiple structures of die 312 may be taken to generate indications of properties of die 312, e.g., via statistical metrics of the measurements. Multiple measurements of a single structure (e.g., structure 302) may be made, to determine properties of the structure. Field selections 306 may indicate a number of measurements taken to determine properties of a structure, of a field, of a die, or the like. Measurements may be taken on-the-fly, subject to constraints of the measurement system. Measurements may be taken in multiple “passes,” e.g., measurements associated with field selections 306 may be separated in time, with measurements of other areas of a substrate occurring between one or more measurements associated with field selections 306.

Measurement system 300 includes measurement instrument 310, such as a measurement apparatus, reflectometry instrument, metrology instrument, or the like. Measurement instrument 310 may be configured to measure one or more properties of die 312. Measurement instrument 310 may be configured to measure thickness, critical dimension, reflectivity, index of refraction, extinction coefficient, or another property of die 312. Measurement instrument 310 may be a pulsed instrument, e.g., may be configured to provide laser pulses to die 312 for performing measurements of die 312.

Measurement instrument 310 may be coupled to measurement system processing device 314, which may be or include general-purpose computing devices, purpose-built computing devices, remote or cloud-based computing capabilities, or the like. Measurement system processing device 314 may provide instructions controlling measurement instrument 310. Measurement processing device 314 may further provide instructions to one or more motors controlling relative position of a substrate, structure, die, field, or the like to measurement instrument 310. Measurement processing device 314 may provide instructions to one or more motors of a substrate support associated with die 312. Measurement processing device 314 may generate a measurement path for the one or more motors to cause motion. Measurement processing device 314 may generate a measurement path subject to one or more constraints of the measurement system 300, such as motion constraints, measurement constraints, application constraints, etc. Measurement system processing device may include and/or execute on-the-fly measurement component 316, which may perform operations associated with performing on-the-fly measurements of a substrate. On-the-fly measurement component 316 may, for example, perform operations for determining an on-the-fly measurement path. On-the-fly measurement component 316 may perform operations for executing on-the-fly measurements. For example, on-the-fly measurement component 316 may generate control signals that are provided to measurement instrument 310 to performing measurement operations. On-the-fly measurement component 316 may generate control signals that are provided to one or more motors, to cause the motors to operate, cause the motors to move, cause the motors to position the substrate relative to measurement instrument 310, or the like. On-the-fly measurement component 316 may provide control signals to one or more other components (e.g., measurement instrument 310, one or more motors, etc.) to cause operations to be performed by the components.

FIG. 4 depicts example measurement path 402 for performing measurements of a substrate 400, according to some embodiments. In some embodiments, it may be natural to take measurements of a number of sites of a substrate in a spiral path. For example, if a substrate support has motor control in (r, θ) space, a spiral path may be the most natural and/or efficient to cover a large portion of the surface of the substrate. A spiral path (or another type of path, for example for a different set-up of motors) may reduce required acceleration, jerk, etc., of motors of the substrate support. A substrate support provided with motors in (x, y) space may naturally follow an advancing back-and-forth measurement path, for example.

An efficient path may not precisely coincide with measurement targets 404. In the case of a substrate including structures such as memory blocks (e.g., a patterned semiconductor wafer), a path generated by convenient operation of motors (e.g., a spiral path generated by constant speed adjustment of both a linear and rotational motor) may not cause alignment of measurement resolution elements with substrate structures. A measurement path guided by convenient operation of motors may cause measurement of regions including overlapping structures, space between structures, or the like. A measurement path 402 may roughly coincide with an efficient path for scanning over the surface of a substrate. A measurement path 402 may be utilized to conform to experimental constraints. A measurement path 402 may be designed such that acceleration, jerk, and timing of arrival of structures within a field of view of a measurement instrument are all maintained within threshold boundary conditions.

A computing device, processing device, algorithm, purpose-built hardware, or the like may be utilized for determining measurement path 402. Measurement path 402 may be associated with a pulsed measurement system, such as a pulsed reflectometry substrate metrology system. A spacing between measurement targets such as measurement target 404 may be determined by a speed of operation and other parameters of one or more motors of the measurement system and a pulse rate, frequency, or period of operation of the measurement system.

Determining measurement path 402 may be subject to one or more constraints of the measurement system. Constraints may include constraints of a substrate support stage utilized during measurement of the substrate. Support stage constraints may include a range of motor speeds, a range of motor accelerations, or other movement constraints of the stage (e.g., jerk). Significant time may be saved by performing measurement on-the-fly, e.g., without waiting for motors, substrates, etc., to settle as motors stop or start, or the like. A measurement path may be determined that achieves one or more target measurement locations while conforming to stage constraints. A measurement path may be determined that targets categories of structures of interest (e.g., maximizing a number of measurements that fall on a single memory block) subject to constraints of the measurement stage (as well as other constraints).

Constraints may include constraints of the measurement apparatus (e.g., reflectometer). Measurement constraints may include restraints related to pulse timing of the measurement apparatus. Constraints may include a range of pulse timings that may be utilized for the measurement apparatus (e.g., a reflectometer may perform at a target quality between 5 and 50 Hz). Constraints may include variations that may be applied to pulse timing without performance falling below a target threshold (e.g., a reflectometer operated at 10 Hz may have pulses varying between 5 Hz and 15 Hz without performance dropping below a target threshold). In some embodiments, a measurement apparatus may be operated with a consistent pulse timing throughout operation.

Constraints may include application constraints, e.g., related to target output of the measurement system. Application constraints may include measurement constraints, such as target measurement areas (e.g., targeting particular heater zones, target areas of a substrate process chamber, fields, dies, or memory blocks of interest, or the like). Application constraints may include confidence constraints, such as target signal-to-noise ratio, target number of measurements for averaging, or the like. Application constraints may include a number of target measurements of a single structure, of one or more structures of a target die, of one or more structures of any single die, of one or more structures of a target field, of any one or more structures included in a target field, of a total number of structures to be measured of the substrate, or the like. Application constraints may include target throughput of the measurement system, e.g., a target maximum measurement time of a substrate.

Determining a measurement path may be based on a variety of constraints, strength or importance of constraints, etc. For example, a measurement path may be a compromise between various constraints of the measurement. A measurement path may include constraints that are absolute, e.g., constraints that must be met in the measurement path. A measurement path may include constraints that are targets, e.g., a target throughput may not be achievable subject to other constraints of the measurement system, but a measurement path determination system may select a path that achieves throughput as close as possible to the target while maintaining the other constraints of the system. Any of the system constraints may be utilized in any way here described, subject to relative targets of the system, thresholds of the measurement system, etc.

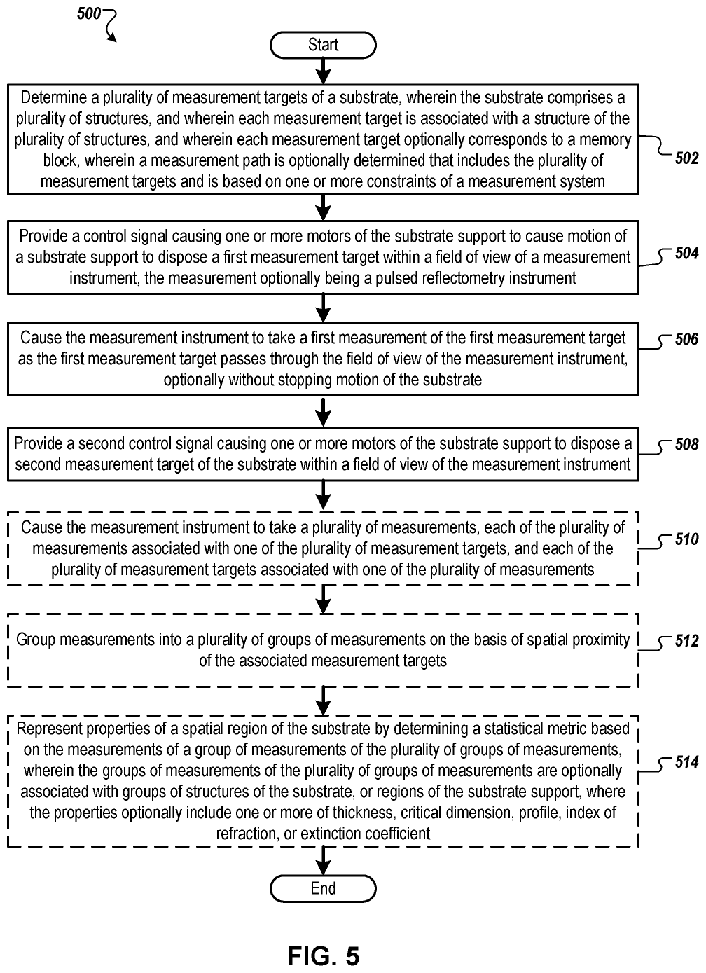

FIG. 5 is a flow diagram of a method 500 associated for performing on-the-fly measurements of a substrate including structures, according to some embodiments. Method 500 may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. Method 500 may be performed by measurement system processing device 314 of FIG. 3, on-the-fly measurement component 316, etc. Method 500 may be performed, in whole or in part, by one or more controllers, e.g., devices that provide instructions to various components of a substrate processing and/or measurement system to perform on-the-fly measurements of a substrate. Method 500 may include providing control signals to operate one or more components, such as a measurement instrument, motors configured to adjust a position of a substrate, or the like. Method 500 may be used to generate measurements and data of a substrate, including data indicating performance of the substrate, performance of a substrate process system, performance of a substrate process procedure, performance of a substrate support, or the like. In some embodiments, a non-transitory machine-readable storage medium stores instructions that, when executed by a processing device, cause the processing device to perform method 500.

For simplicity of explanation, method 500 is depicted and described as a series of operations. However, operations in accordance with this disclosure can occur in various orders and/or concurrently and with other operations not presented and described herein. Furthermore, not all illustrated operations may be performed to implement method 500 in accordance with the disclosed subject matter. In addition, those skilled in the art will understand and appreciate that method 500 could alternatively be represented as a series of interrelated states via a state diagram or events.

Referring now to FIG. 5, at block 502, processing logic determines a plurality of measurement targets of a substrate. The measurement targets may be locations of interest of the substrate, associated with locations of interest of a substrate process system, associated with locations of interest of a substrate support, or the like. The substrate may include a plurality of structures, such as memory blocks, of interest. Each measurement target may be associated with a structure of the plurality of structures. A measurement target may be a structure, e.g., any measurement including the structure. A measurement target may be a specific location of a structure. Each measurement target may optionally correspond to a memory block. In some embodiments, a measurement target may be measured multiple times in a measurement procedure. For example, a substrate may be rotated several times to perform a number of measurements of the surface, and a measurement target may be measured multiple times during subsequent rotations of the substrate. In some embodiments, a measurement path may be generated by processing logic. The measurement path may align, approximately align, or be similar to a “natural” sweep of the substrate, e.g., a sweeping pattern suggested by a motor arrangement of the substrate support. The measurement path may enable measurement of the plurality of measurement targets. As an example, for a substrate support with a linear and rotational motor control, a measurement path may approximately spiral over the surface of the substrate, with variations from an ideal spiral to ensure that the plurality of measurement targets are measured and various constraints of the system are maintained (e.g., motor constraints, measurement instrument constraints, application constraints, etc.).

At block 504, processing logic operates one or more motors of the substrate support (e.g., by providing control signals to the one or more motors) to cause motion of the substrate support to dispose a first measurement target within a field of view of a measurement instrument. The motors may be configured to cause relative motion between the measurement instrument and the substrate, e.g., in some embodiments motors may be associated with the measurement instrument. The measurement instrument may be an optical measurement instrument. The measurement instrument may be a pulsed instrument, such as a pulsed laser-based instrument. The measurement instrument may be a reflectometry instrument, such as an infrared reflectometer.

At block 506, processing logic causes the measurement instrument to take a first measurement of the first measurement target. Causing the measurement instrument to take a first measurement may include providing one or more control signals to the measurement instrument, providing instructions to the measurement instrument, or the like. The first measurement may be taken as the first measurement target passes through the field of view of the measurement instrument. In some embodiments, the first measurement may be taken without stopping motion of the substrate relative to the measurement instrument (e.g., without stopping one or more motors of the system), e.g., in an on-the-fly manner.

At block 508, processing logic operates the one or more motors of the substrate support (e.g., by providing further control signals to the one or more motors) to dispose a second measurement target of the substrate within a field of view of the measurement instrument. The second measurement target may share one or more features with the first measurement target. Measurement of the second target may be performed. Measurement of the second target may be performed in an on-the-fly manner.

At block 510, processing logic optionally causes the measurement instrument to take a plurality of measurements. Each of the plurality of measurements may be associated with one of the plurality of measurement targets. Each of the plurality of measurement targets may be associated with one of the plurality of measurements.

At block 512, processing logic groups measurements into a plurality of groups of measurements on the basis of spatial proximity of the associated measurement targets. In some embodiments, measurements may be grouped based on belonging to a common category, such as belonging to the same field, the same die, a die situated in the same position compared to other dies in other fields, a structure situated in the same relative position as other structures of other dies, or the like.

At block 514, processing logic represents properties of a spatial region of the substrate by determining a statistical metric based on the measurements of a group of measurements of the plurality of groups of measurements. The groups of measurements of the plurality of groups of measurements are optionally associated with groups of structures of the substrate, or regions of the substrate support. Properties measured by the system may include thickness, critical dimension, profile, index of refraction, extinction coefficient, or another property.

In some embodiments, measurements performed on a substrate in an on-the-fly manner (e.g., in one operation including a sequence of measurements) may include measurements targeting different properties, utilizing different measurement instruments, targeting different wavelengths, or the like. For example, upon multiple passes of a region of a substrate through a field of view of one or more measurement instruments, different measurements, measurements associated with different properties, or the like may be performed. For example, in a measurement system including a rotational motor, on a first pass on-the-fly measurements may be made for determining a thickness of a substrate, and on a second pass on-the-fly measurements may be made for determining a second property of the same region of the substrate, such as thickness of an upper film layer.

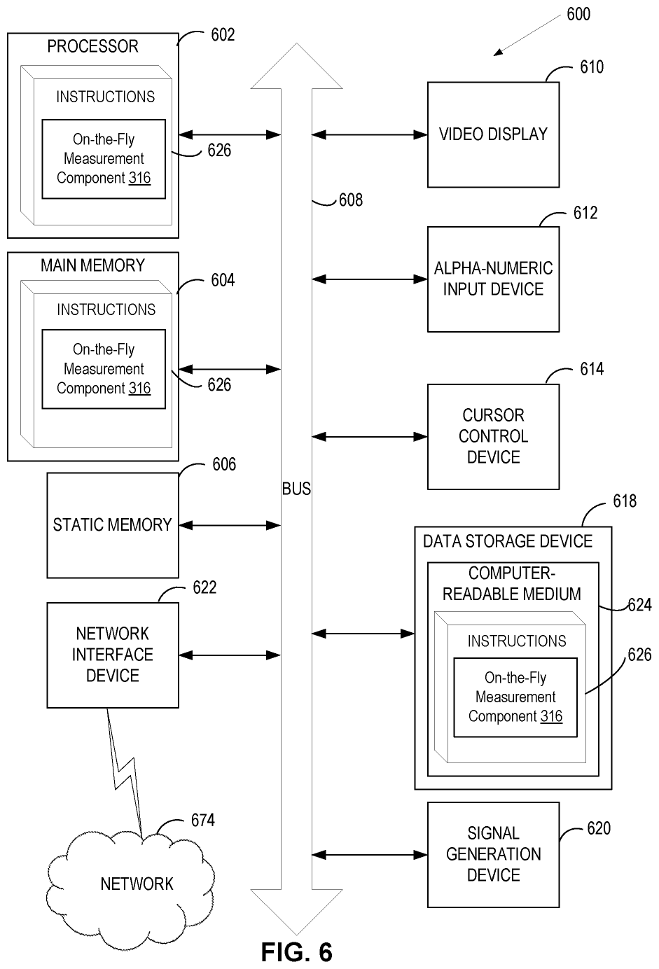

FIG. 6 is a block diagram illustrating a computer system 600, according to some embodiments. In some embodiments, computer system 600 may be connected (e.g., via a network, such as a Local Area Network (LAN), an intranet, an extranet, or the Internet) to other computer systems. Computer system 600 may operate in the capacity of a server or a client computer in a client-server environment, or as a peer computer in a peer-to-peer or distributed network environment. Computer system 600 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein. Computer system 600 may be or include any combination of devices for performing operations of measurement system processing device 314 of FIG. 3, executing methods of on-the-fly measurement component 316, or the like.

In a further aspect, the computer system 600 may include a processing device 602, a volatile memory 604 (e.g., Random Access Memory (RAM)), a non-volatile memory 606 (e.g., Read-Only Memory (ROM) or Electrically-Erasable Programmable ROM (EEPROM)), and a data storage device 618, which may communicate with each other via a bus 608.

Processing device 602 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 600 may further include a network interface device 622 (e.g., coupled to network 674). Computer system 600 also may include a video display unit 610 (e.g., an LCD), an alphanumeric input device 612 (e.g., a keyboard), a cursor control device 614 (e.g., a mouse), and a signal generation device 620.

In some embodiments, data storage device 618 may include a non-transitory computer-readable storage medium 624 (e.g., non-transitory machine-readable medium) on which may store instructions 626 encoding any one or more of the methods or functions described herein, including instructions encoding components of FIG. 3 (e.g., on-the-fly measurement component 316, etc.) and for implementing methods described herein.

Instructions 626 may also reside, completely or partially, within volatile memory 604 and/or within processing device 602 during execution thereof by computer system 600, hence, volatile memory 604 and processing device 602 may also constitute machine-readable storage media.

While computer-readable storage medium 624 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” “reducing,” “generating,” “correcting,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and embodiments, it will be recognized that the present disclosure is not limited to the examples and embodiments described. The scope of the disclosure should be determined with reference to the following claims, along with the full scope of equivalents to which the claims are entitled.

What is claimed is:

1. A method, comprising:
determining a plurality of measurement targets of a substrate, wherein the substrate comprises a plurality of structures, and wherein each measurement target is associated with a structure of the plurality of structures;
providing a first control signal causing one or more motors to cause motion of a substrate support to dispose a first measurement target within a field of view of a measurement instrument;
causing the measurement instrument to take a first measurement of the first measurement target as the first measurement target passes through the field of view of the measurement instrument; and
providing a second control signal causing the one or more motors of the substrate support to dispose a second measurement target of the substrate within the field of view of the measurement instrument.

2. The method of claim 1, wherein the measurement instrument comprises a pulsed reflectometry instrument.

3. The method of claim 1, further comprising:
causing the measurement instrument to take a plurality of measurements, each of the plurality of measurements associated with one of the plurality of measurement targets, and each of the plurality of measurement targets associated with one of the plurality of measurements;
grouping measurements into a plurality of groups of measurements based on spatial proximity of the associated measurement targets; and
representing one or more properties of a spatial region of the substrate by determining a statistical metric based on the measurements of a group of measurements of the plurality of groups of measurements.

4. The method of claim 3, wherein the groups of measurements of the plurality of groups of measurements are associated with groups of structures of the substrate.

5. The method of claim 3, wherein the groups of measurements of the plurality of groups of measurements are associated with regions of the substrate support.

6. The method of claim 3, wherein the one or more properties comprise:
substrate thickness;
film thickness;
critical dimension;
index of refraction; or
extinction coefficient.

7. The method of claim 1, where each measurement target corresponds to a memory block.

8. The method of claim 1, wherein the first measurement is taken without stopping motion of the substrate support.

9. The method of claim 1, further comprising determining a measurement path comprising the plurality of measurement targets, wherein the measurement path is determined based on one or more constraints of a measurement system used to perform the first measurement.

10. A non-transitory machine-readable storage medium storing instructions which, when executed, cause a processing device to perform operations comprising:
determining a plurality of measurement targets of a substrate, wherein the substrate comprises a plurality of structures, and wherein each measurement target is associated with a structure of the plurality of structures;
providing a first control signal causing one or more motors to cause motion of a substrate support to dispose a first measurement target within a field of view of a measurement instrument;
causing the measurement instrument to take a first measurement of the first measurement target as the first measurement target passes through the field of view of the measurement instrument; and
providing a second control signal causing the one or more motors of the substrate support to dispose a second measurement target of the substrate within the field of view of the measurement instrument.

11. The non-transitory machine-readable storage medium of claim 10, wherein the operations further comprise:
causing the measurement instrument to take a plurality of measurements, each of the plurality of measurements associated with one of the plurality of measurement targets, and each of the plurality of measurement targets associated with one of the plurality of measurements;
grouping measurements into a plurality of groups of measurements based on spatial proximity of the associated measurement targets; and
representing one or more properties of a spatial region of the substrate by determining a statistical metric based on the measurements of a group of measurements of the plurality of groups of measurements.

12. The non-transitory machine-readable storage medium of claim 11, wherein the groups of measurements of the plurality of groups of measurements are associated with groups of structures of the substrate.

13. The non-transitory machine-readable storage medium of claim 11, wherein the groups of measurements of the plurality of groups of measurements are associated with regions of the substrate support.

14. The non-transitory machine-readable storage medium of claim 11, wherein the one or more properties comprise:
substrate thickness;
film thickness;
critical dimension;
index of refraction; or
extinction coefficient.

15. The non-transitory machine-readable storage medium of claim 11, further comprising determining a measurement path comprising the plurality of measurement targets, wherein the measurement path is determined based on one or more constraints of a measurement system used to perform the first measurement.

16. A system, comprising memory and a processing device coupled to the memory, wherein the processing device is configured to:
determine a plurality of measurement targets of a substrate, wherein the substrate comprises a plurality of structures, and wherein each measurement target is associated with a structure of the plurality of structures;
provide a first control signal to cause one or more motors to cause motion of a substrate support to dispose a first measurement target within a field of view of a measurement instrument;
cause the measurement instrument to take a first measurement of the first measurement target as the first measurement target passes through the field of view of the measurement instrument; and
provide a second control signal to cause the one or more motors of the substrate support to dispose a second measurement target of the substrate within the field of view of the measurement instrument.

17. The system of claim 16, wherein the processing device is further configured to:
cause the measurement instrument to take a plurality of measurements, each of the plurality of measurements associated with one of the plurality of measurement targets, and each of the plurality of measurement targets associated with one of the plurality of measurements;
group measurements into a plurality of groups of measurements based on spatial proximity of the associated measurement targets; and
represent one or more properties of a spatial region of the substrate by determining a statistical metric based on the measurements of a group of measurements of the plurality of groups of measurements.

18. The system of claim 17, wherein the groups of measurements of the plurality of groups of measurements are associated with groups of structures of the substrate.

19. The system of claim 16, wherein the first measurement is taken without stopping motion of the substrate support.

20. The system of claim 16, wherein the processing device is further configured to determine a measurement path comprising the plurality of measurement targets, wherein the measurement path is determined based on one or more constraints of a measurement system used to perform the first measurement.
